(19) United States
(12) Patent Application Publication
(10) Pub. No.: US 2012/0153471 A1
(43) Pub. Date: Jun. 21, 2012

(54) SEMICONDUCTOR DEVICE AND SEMICONDUCTOR PACKAGE

(75) Inventors: Takeshi WATANABE, Yokkaichi-Shi (JP); Yuji Karakane, Yokkaichi-Shi (JP); Takashi Imoto, Yokkaichi-Shi (JP)

(73) Assignee: KABUSHIKI KAISHA TOSHIBA, Tokyo (JP)

(21) Appl. No.: 13/235,408

(22) Filed: Sep. 18, 2011

(30) Foreign Application Priority Data
Dec. 17, 2010 (JP) 2010-281638

(51) Int. Cl. H01L 23/485

(52) U.S. Cl. 257/738; 257/E23.021

(57) ABSTRACT

A semiconductor device according to the present embodiment includes a substrate including wirings. At least one first semiconductor chip is mounted on a first surface of the substrate and is electrically connected to any of the wirings. A first metal ball is provided on the first surface of the substrate and is electrically connected to the first semiconductor chip through any of the wirings. A first resin seals the wirings, the first semiconductor chip, and the first metal ball on the first surface of the substrate. A top of the first metal ball protrudes from a surface of the first resin and is exposed.

### CROSS REFERENCE TO RELATED APPLICATIONS

This application is based upon and claims the benefit of priority from the prior Japanese Patent Application No. 2010-281638, filed on Dec. 17, 2010, the entire contents of which are incorporated herein by reference.

### FIELD

The embodiments of the present invention relate to a semiconductor device and a semiconductor package.

### BACKGROUND

Conventionally, in order to reduce semiconductor device mounting area, PoP (Package on Package) technology is used. A PoP is formed by stacking a plurality of semiconductor devices (sub-packages), in which semiconductor chips are sealed with a resin, on top of each other on a wiring substrate.

A semiconductor device has a solder ball on its back surface that is not sealed with a resin, and is electrically connected to another semiconductor device by the solder ball. In this case, in order that a solder ball of a top semiconductor device among a plurality of stacked semiconductor devices is connected to a bottom semiconductor device, a part of a front surface of the bottom semiconductor device is not sealed with a resin. Therefore, in the conventional PoP, the package configurations of the top and bottom semiconductor devices necessarily differ from each other.

When the package configurations differ from each other, there is required a molding die for resin sealing which is designed specifically for each of a plurality of semiconductor devices to be stacked. In this case, the cost of manufacturing molding dies increases. In addition, since the plurality of stacked semiconductor devices have different packages, the semiconductor devices need to be packaged distinctly.

Furthermore, semiconductor devices having different packages have different degrees of warpage and different warpage directions. Hence, when a plurality of semiconductor devices having different packages are stacked, it is difficult to adjust the warpage directions and degrees of warpage of the semiconductor devices to match each other. When a semiconductor device gets thinner, it becomes more difficult to adjust the degrees of warpage and warpage directions of a plurality of semiconductor devices to match each other.

When multiple semiconductor devices are stacked on top of each other in a multiplayer fashion, if the semiconductor devices have different packages, the PoP assembly time (Turn Around Time) increases. Besides, due to the failure of a single semiconductor device, the whole PoP structure including that semiconductor device may fail. This causes an increase in cost, low yields, and low reliability.

### BRIEF DESCRIPTION OF THE DRAWINGS

FIG. 1 is a cross-sectional view showing a structure of a semiconductor package 1 having a PoP structure according to a first embodiment;

FIGS. 2A to 2C are cross-sectional views showing a method of manufacturing a semiconductor device 20a according to the first embodiment;

FIGS. 3 and 4 are illustrative diagrams more specifically showing the sealing step described with reference to FIG. 2C;

FIGS. 5A to 5C are cross-sectional views showing a method of manufacturing a semiconductor package (PoP) 1 according to the first embodiment;

FIG. 6 is a cross-sectional view showing one of the semiconductor packages according to the first embodiment;

FIG. 7 is a cross-sectional view showing the configurations of semiconductor devices and a semiconductor package 2 according to a second embodiment;

FIGS. 8A to 8C are cross-sectional views showing a method of manufacturing a semiconductor package (PoP) 2 according to the second embodiment;

FIG. 9 is a cross-sectional view showing one of the semiconductor packages according to the second embodiment;

FIG. 10 is a cross-sectional view showing the configurations of semiconductor devices 23a and 23b and a semiconductor package 3 according to a third embodiment;

FIGS. 11A to 11D are cross-sectional views showing a method of manufacturing a semiconductor device 23a according to the third embodiment;

FIGS. 12A to 12C are cross-sectional views showing a method of manufacturing a semiconductor package (PoP) 3 according to the third embodiment; and

FIG. 13 is a cross-sectional view showing one of the semiconductor packages according to the third embodiment.

### DETAILED DESCRIPTION

A semiconductor device according to the present embodiment includes a substrate including wirings. At least one first semiconductor chip is mounted on a first surface of the substrate and is electrically connected to any of the wirings. A first metal ball is provided on the first surface of the substrate and is electrically connected to the first semiconductor chip through any of the wirings. A first resin seals the wirings, the first semiconductor chip, and the first metal ball on the first surface of the substrate. A top of the first metal ball protrudes from a surface of the first resin and is exposed.

Hereafter, embodiments according to the present invention will be described with reference to the drawings. The embodiments are not intended to limit the present invention.

### First Embodiment

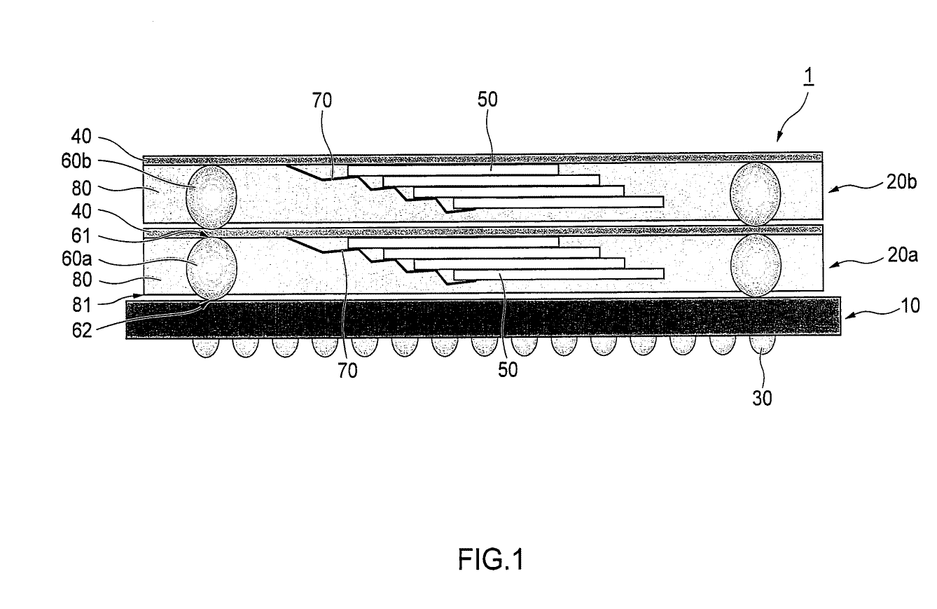

FIG. 1 is a cross-sectional view showing a structure of a semiconductor package 1 having a PoP structure according to a first embodiment. The semiconductor package 1 according to the present embodiment includes a wiring substrate 10 and semiconductor devices 20a and 20b. Note that in FIG. 1 the semiconductor package 1 has only two semiconductor devices 20a and 20b stacked on top of each other, but may have three or more semiconductor devices stacked on top of each other. Note also that for convenience of description, a surface side, on which a semiconductor chip is mounted, is described as a front surface (top side) of a semiconductor device, and a surface side, on which a semiconductor device is mounted, is described as a front surface (top side) of a semiconductor package. However, directions indicated in the description (up, down, left, right, front, back, etc.) are relative directions in reference to the aforementioned front surface (top side) and thus may differ from absolute directions in reference to the direction of gravity.

The wiring substrate 10 serving as a second substrate has, on its front surface, conductive wirings (not shown) formed in a desired pattern and has solder balls 30 on its back surface. The wiring substrate 10 may be a so-called printed-circuit board and has an insulating layer of, for example, glass epoxy.

The semiconductor devices 20a and 20b are stacked on the wiring substrate 10. The semiconductor device 20a is electrically connected to any of the wirings on the wiring substrate 10 by solder balls 60a. The semiconductor device 20b is electrically connected to wirings or bumps on a back surface of the semiconductor device 20a by solder balls 60b.

The semiconductor devices 20a and 20b have the same package structure and thus the structure of only the semiconductor device 20a will be described, and description of the semiconductor device 20b is omitted. Note that semiconductor chips 50 included in the semiconductor devices 20a and 20b may differ from each other.

The semiconductor device 20a includes a substrate 40 serving as a first substrate, the plurality of semiconductor chips 50, the solder balls 60a, a gold wire 70, and a sealing resin 80. The substrate 40 is thinner than the wiring substrate 10, and is made of, for example, insulating materials such as a glass epoxy resin. The substrate 40 has conductive wirings on its front surface where the semiconductor chips 50 are mounted. The back surface of the substrate 40 also has conductive wirings or bumps formed thereon. The wirings or bumps are electrically connected to any of the wirings on the front surface of the substrate 40.

The plurality of semiconductor chips 50 are placed on the front surface of the substrate 40 and are electrically connected to any point of the wirings on the substrate 40 through the gold wire 70. Each semiconductor chip 50 may be a semiconductor chip in which any integrated circuit is formed on a semiconductor substrate. For example, the semiconductor chips 50 may be NAND flash memory chips.

The solder balls 60a serving as metal balls are formed on the front surface of the substrate 40 and are electrically connected to any of the semiconductor chips 50 through the wirings on the substrate 40 and the gold wire 70. The material of the solder balls 60a and 60b does not necessarily need to be solder, and the solder balls 60a and 60b may be any conductive metal ball.

The sealing resin 80 seals the wirings, the gold wire 70, the plurality of semiconductor chips 50, and the solder balls 60a on the front surface of the substrate 40 to protect them.

Each solder ball 60a is exposed from a surface 81 of the sealing resin 80 at a top portion 62 which is on the opposite side of a top portion 61 being in contact with the substrate 40. The solder ball 60a protrudes from the surface 81 of the sealing resin 80. Namely, as viewed from the substrate 40, the top portion 62 of the solder ball 60a is located away from the surface 81 of the sealing resin 80. Note that the solder balls 60b may have the same configuration as the solder balls 60a.

Next, a method of manufacturing a semiconductor device 20a will be described.

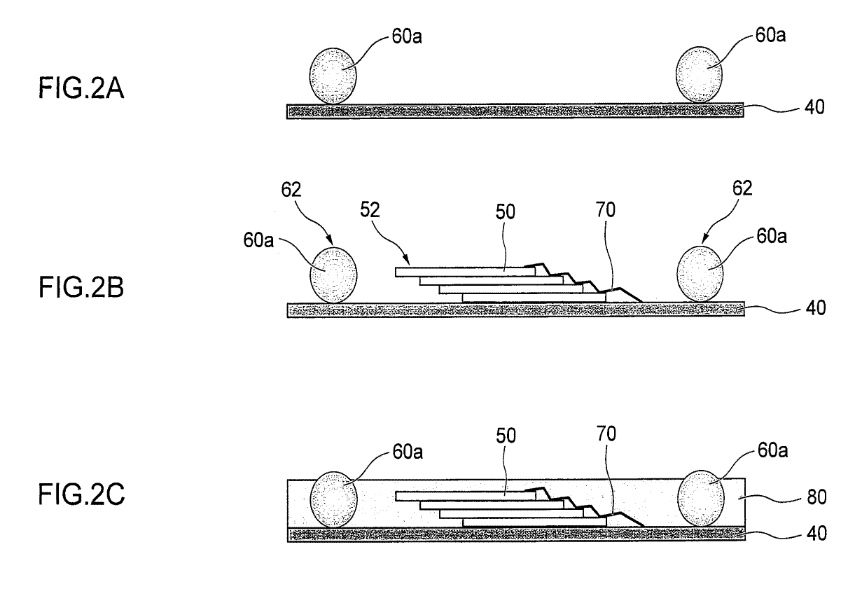

FIGS. 2A to 2C are cross-sectional views showing a method of manufacturing a semiconductor device 20a according to the first embodiment. A method of manufacturing a semiconductor device 20b is the same as that for the semiconductor device 20a and thus description thereof is omitted. Note that although FIGS. 2A to 2C show cross sections of only one semiconductor device 20a, in practice, a plurality of semiconductor devices 20a are formed so as to be continuously connected to each other by the substrate 40.

First, as shown in FIG. 2A, a substrate 40 is prepared. The substrate 40 has, as described above, an insulating layer of glass epoxy, etc., and has conductive wirings formed on its front surface and/or back surface. Solder balls 60a are formed on the substrate 40 so as to come into contact with any of the wirings on the front surface of the substrate 40.

Then, as shown in FIG. 2B, a single or plurality of semiconductor chips 50 are mounted on the front surface of the substrate 40, and pads of the semiconductor chips 50 are electrically connected to the wirings on the substrate 40 by a gold wire 70. Here, the semiconductor chips 50 are mounted on the same surface as a surface (front surface) of the substrate 40 where the solder balls 60a are formed. The structures and functions of the plurality of semiconductor chips 50 may be the same or may differ from each other. The gold wire 70 may be any low resistance metal wire and is not particularly limited.

Then, as shown in FIG. 2C, the semiconductor chips 50, the gold wire 70, and the solder balls 60a which are mounted on the front surface of the substrate 40 are sealed with a resin 80. At this time, while all of the plurality of semiconductor chips 50 and the whole gold wire 70 are sealed with the resin 80, top portions 62 of the solder balls 60a are exposed.

In the step shown in FIG. 2B, the top portions 62 of the solder balls 60a need to be at a location higher than a top surface 52 of one of the semiconductor chips 50 mounted uppermost. In other words, the top portions 62 of the solder balls 60a are further away from the substrate 40 than the top surface 52 of one of the semiconductor chips 50 mounted uppermost. Accordingly, in the sealing step shown in FIG. 2C, while all of the plurality of semiconductor chips 50 and the whole gold wire 70 are sealed with the resin 80, the top portions 62 of the solder balls 60a can be exposed.

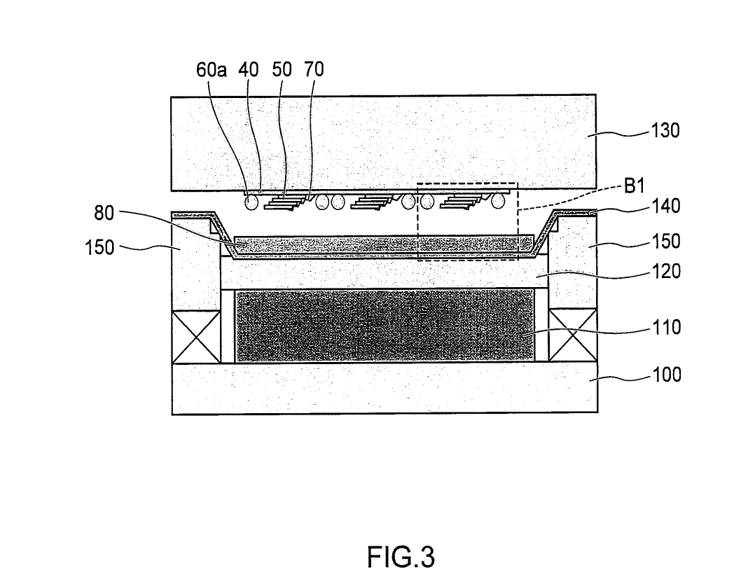

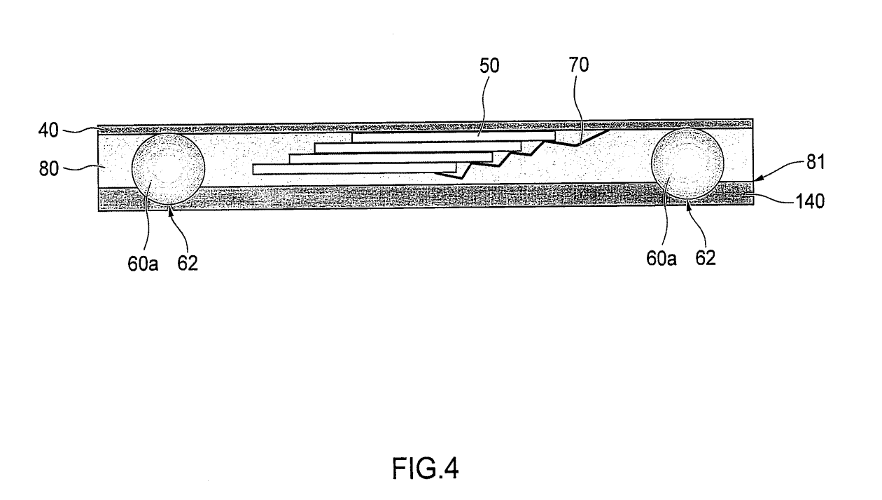

FIGS. 3 and 4 are illustrative diagrams more specifically showing the sealing step described with reference to FIG. 2C. FIG. 4 is an enlarged diagram of a dashed-line area B1 in FIG. 3. FIG. 3 shows a state in which the semiconductor chips 50, the gold wire 70, and the solder balls 60a are resin-sealed in a mold forming apparatus. The mold forming apparatus includes a substrate 100, a leaf spring 110, a mold cavity 120, a upper die 130, and side portions 150.

The leaf spring 110 is provided on the substrate 100 and elastically supports the mold cavity 120. The substrate 40, the semiconductor chips 50, the gold wire 70, and the solder balls 60a are sandwiched between the mold cavity 120 and the upper die 130. And, the semiconductor chips 50, the gold wire 70, and the solder balls 60a are sealed with a melted sealing resin 80. At this time, the upper die 130 descends toward the mold cavity 120 with the substrate 40 being stuck fast to the upper die 130, in order to press the substrate 40, the semiconductor chips 50, the gold wire 70, and the solder balls 60a against the melted sealing resin 80 in the mold cavity 120, while the upper die 130 presses down the side portions 150.

In this way, the sealing resin 80 seals the semiconductor chips 50, the gold wire 70, and the solder balls 60a by a molding die of the mold cavity 120.

Here, a mold release film 140 is put on the mold cavity 120 and the melted sealing resin 80 is placed on the release film 140. Therefore, when the upper die 130 descends toward the mold cavity 120, as shown in FIG. 4, the solder balls 60a are pressed against the mold release film 140.

The mold release film 140 is, for example, an elastic film with a thickness of 25 μm to 75 μm, and is composed of a material that elastically receives the top portions 62 of the solder balls 60a when the solder balls 60a are pressed against it. Specifically, a film using fluoroplastics (PTFE, ETFE, etc.) as a principal material can be used as the mold release film 140. By using such a mold release film 140, after molding, the top portions 62 of the solder balls 60a are exposed protruding from a surface 81 of the sealing resin 80. For example, the top portions 62 of the solder balls 60a protrude by 90% or more of the thickness of the mold release film 140 (e.g., 22.5 μm to 75 μm) from the surface 81 of the sealing resin 80. Note, however, that the solder balls 60a should not penetrate through the mold release film 140.

A surface of the mold release film 140 may be mirror-like or may be satin-like. However, it is preferable that the mold release film 140 be a mirror-like film with small unevenness on its surface to suppress the occurrence of resin fins on the top portions 62 so that the top portions 62 of the solder balls 60a distinctly protrude from the surface 81 of the sealing resin 80.

Furthermore, in the present embodiment, as shown in FIG. 2B, the top portions 62 of the solder balls 60a are further away from the substrate 40 than the top surface 52 of the semiconductor chip 50. Hence, upon molding, the semiconductor chips 50 do not come into contact with the mold release film 140 or the mold cavity 120 and thus are not subjected to stress.

After resin sealing, by dicing of the substrate 40, semiconductor devices 20a are individualized.

Next, a method of assembling a semiconductor package (PoP) will be described.

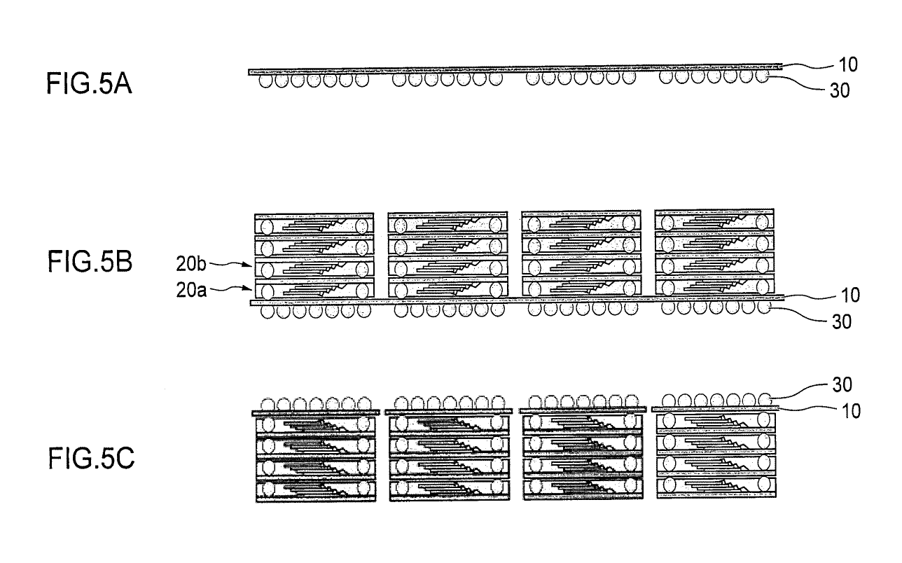

FIGS. 5A to 5C are cross-sectional views showing a method of manufacturing a semiconductor package (PoP) 1 according to the first embodiment. As shown in FIG. 5A, a wiring substrate 10 having solder balls 30 on its back surface is prepared.

Then, as shown in FIG. 5B, individualized semiconductor devices 20a and 20b are mounted on a front surface of the wiring substrate 10. Solder balls 60a of a semiconductor device 20a according to the present embodiment are in contact with wirings on the wiring substrate 10, and solder balls 60b of a semiconductor device 20b are in contact with wirings on a back surface of the semiconductor device 20a.

Top portions 62 of the solder balls 60a of the semiconductor device 20a protrude from a surface 81 of a sealing resin 80 and are exposed. Therefore, in the semiconductor device 20a, the solder balls 60a can be electrically connected to wirings on the wiring substrate 10 without bringing the sealing resin 80 into contact with the wiring substrate 10. Top portions 62 of the solder balls 60b of the semiconductor device 20b also protrude from a surface 81 of a sealing resin 80 and are exposed. Therefore, in the semiconductor device 20b, the solder balls 60b can be electrically connected to wirings on the back surface of the semiconductor device 20a without bringing the sealing resin 80 into contact with the semiconductor device 20a. Solder balls of other semiconductor devices shown in FIG. 5B are also electrically connected to wirings of semiconductor devices or the wiring substrate 10 present thereunderneath.

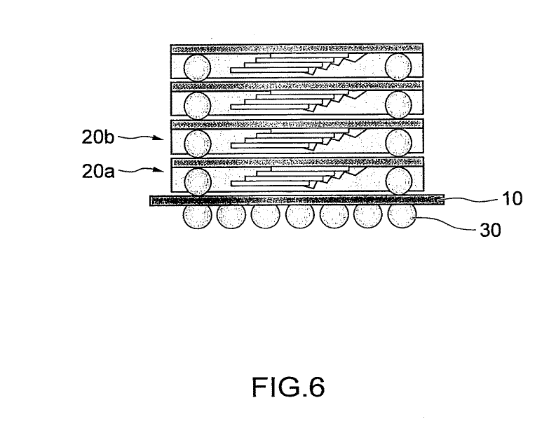

Then, as shown in FIG. 5C, by cutting (dicing, for example) the wiring substrate 10, PoP structures are individualized. By this, a semiconductor package 1 having a PoP structure such as that shown in FIG. 6 is completed.

According to the present embodiment, solder balls 60a are formed on the same surface (front surface) as a surface of a substrate 40 where a sealing resin 80 is formed. Although the solder balls 60a are sealed with the sealing resin 80, top portions 62 of the solder balls 60a protrude from a surface of the sealing resin 80 and are exposed. By such a configuration, despite the fact that semiconductor devices 20a and 20b have the same package structure, the semiconductor devices 20a and 20b can be placed in a PoP structure.

Note that when solder balls are formed on a surface (back surface) which is on the opposite side of a surface of a substrate where a sealing resin is provided, another semiconductor device present on the side of the back surface of the substrate does not have a sealing resin at the locations of the solder balls in order to obtain an electrical connection with the solder balls. Therefore, a plurality of semiconductor devices result in having different package configurations.

On the other hand, according to the present embodiment, since the package structures of semiconductor devices 20a and 20b to be stacked on top of each other are formed in the same manner, the same molding die for resin sealing can be used for the semiconductor devices 20a and 20b. Hence, the semiconductor devices 20a and 20b can be formed in the same package step, which leads to a reduction in the cost of a semiconductor package 1.

Since the semiconductor devices 20a and 20b have the same package structure, their degrees of warpage (distortion) and warpage directions (distortion directions) have substantially the same tendency. Hence, the differences in warpage direction and the degree of warpage between the semiconductor devices 20a and 20b are small. In addition, when the thickness of the packages of the semiconductor devices 20a and 20b is reduced, the degree of warpage of the semiconductor devices 20a and 20b increases; however, in that case, too, stacking of the semiconductor devices 20a and 20b on top of each other is facilitated. As a result, the manufacturing cost of the semiconductor devices 20a and 20b can be reduced and the size of the whole PoP structure can be reduced. Adjusting the warpage tendencies of the semiconductor devices 20a and 20b to match each other can suppress a contact failure between the semiconductor devices, etc., and thus can also lead to an improvement in yields and an improvement in reliability.

Furthermore, when multiple semiconductor devices are stacked on top of each other in a multilayer fashion as shown in FIG. 6, if the semiconductor devices have the same package, the assembly time of a semiconductor package is reduced.

### Second Embodiment

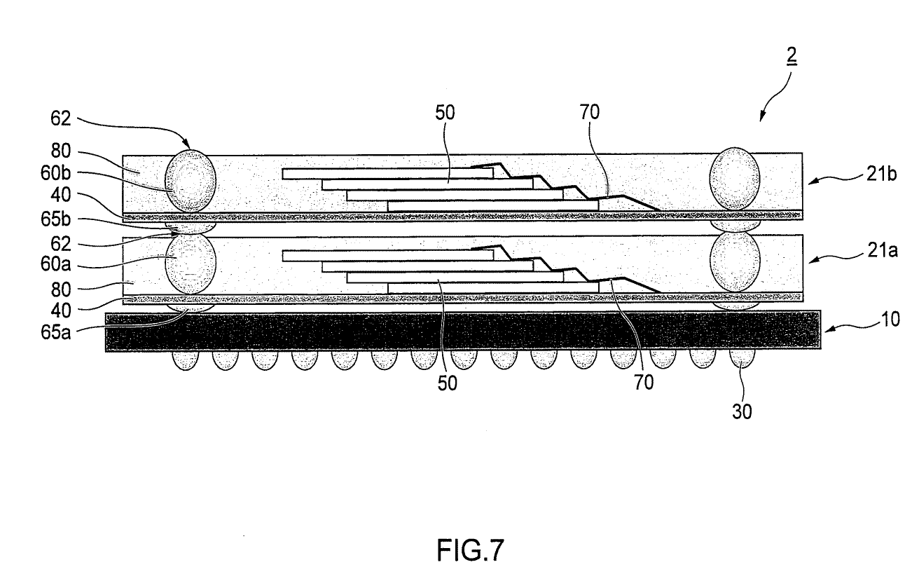

FIG. 7 is a cross-sectional view showing the configurations of semiconductor devices and a semiconductor package 2 according to a second embodiment. Semiconductor devices 21a and 21b according to the second embodiment not only have solder balls 60a and 60b on front surfaces of their respective substrates 40, but also have solder balls (bumps) 65a and 65b on back surfaces of the substrates 40. In the semiconductor package 2, the semiconductor devices 21a and 21b are placed such that their back surface sides face toward a wiring substrate 10. Namely, the semiconductor devices of the semiconductor package 2 according to the second embodiment are placed in a manner such that semiconductor devices of a semiconductor package 1 according to the first embodiment are inverted (turned upside down).

The solder balls 60a on the front surface of the substrate 40 of the semiconductor device 21a are in contact with the solder balls 65b on the back surface of the substrate 40 of the semiconductor device 21b placed on the semiconductor device 21a, and the solder balls 65a on the back surface of the substrate 40 of the semiconductor device 21a are in contact with wirings on the wiring substrate 10. The solder balls 60b on the front surface side of the substrate 40 of the semiconductor device 21b are in contact with solder balls on a back surface of a substrate of another semiconductor device (not shown) which is further placed on the semiconductor device 21b. Namely, the semiconductor device 21a is electrically connected to wirings on the wiring substrate 10 by the solder balls 65a, and the semiconductor device 21b is electrically connected to the solder balls 60a of the semiconductor device 21a by the solder balls 65b.

Other configurations of the semiconductor devices and semiconductor package according to the second embodiment may be the same as those according to the first embodiment.

The solder balls 65a may be formed in a manner such that after sealing semiconductor chips 50 with a sealing resin 80, as shown in FIG. 2C, solder balls 65a are printed or coated on the back surface of the substrate 40. The solder balls 65b are also formed in the same manner as the solder balls 65a. Other manufacturing steps of the semiconductor devices 21a and 21b according to the second embodiment may be the same as those of semiconductor devices 20a and 20b according to the first embodiment.

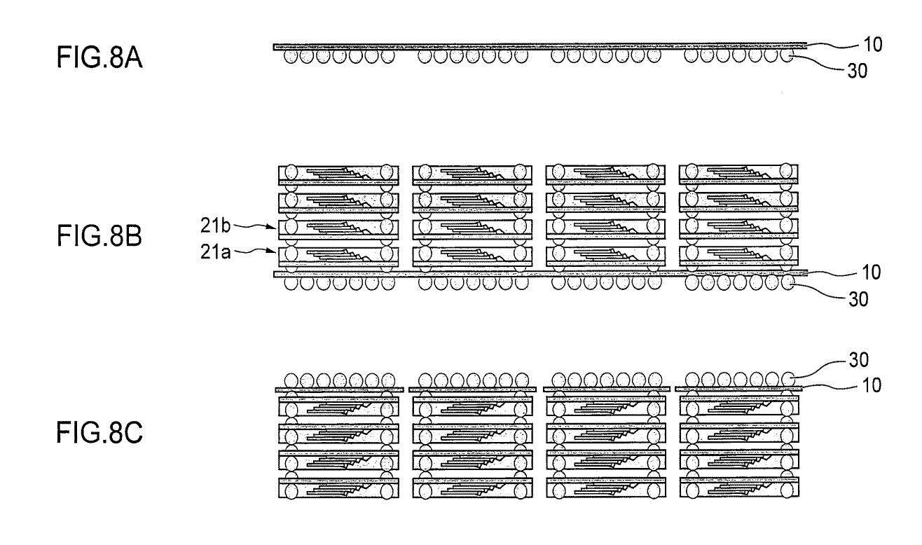

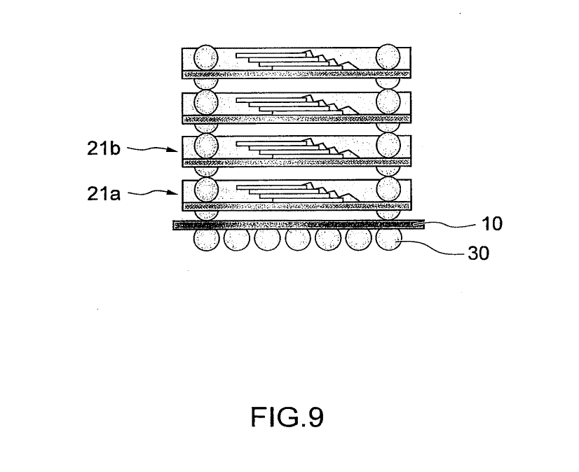

FIGS. 8A to 8C are cross-sectional views showing a method of manufacturing a semiconductor package (PoP) 2 according to the second embodiment. In the second embodiment, each of semiconductor devices 21a and 21b is placed in a manner such that semiconductor devices shown in FIGS. 5B and 5C are inverted (turned upside down). Other portions of the method of manufacturing the semiconductor package 2 according to the second embodiment are the same as those of the method of manufacturing a semiconductor package 1 according to the first embodiment. In FIG. 8C, when semiconductor packages are individualized by dicing, as shown in FIG. 9, a semiconductor package 2 is completed.

Semiconductor devices 21a and 21b according to the second embodiment have solder balls 60a and 60b on front surfaces of their respective substrates 40, and have solder balls 65a and 65b on back surfaces of the substrates 40. By the solder balls 65b of the semiconductor device 21b coming into contact with the solder balls 60a of the semiconductor device 21a, the distance between the semiconductor devices 21a and 21b is maintained and thus sealing resins 80 of the semiconductor devices 21a and 21b can be securely prevented from contacting with each other. Furthermore, the second embodiment has the same advantageous effects as the first embodiment.

### Third Embodiment

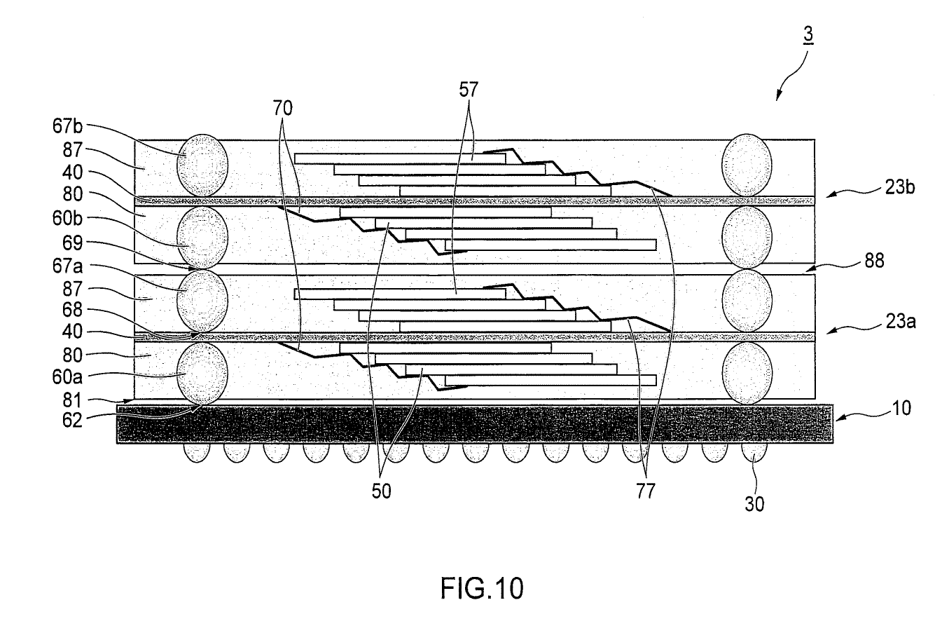

FIG. 10 is a cross-sectional view showing the configurations of semiconductor devices 23a and 23b and a semiconductor package 3 according to a third embodiment. The configurations of a wiring substrate 10 and solder balls 30 may be the same as those of the first embodiment. Note that for convenience of description, a surface side where semiconductor chips are mounted first is described as a front surface (top side) of a semiconductor device. However, directions indicated in the description (up, down, left, right, front, back, etc.) are relative directions in reference to the aforementioned front surface (top side) and thus may differ from absolute directions in reference to the direction of gravity.

In the semiconductor package 3 according to the third embodiment, front side solder balls 60a of the semiconductor device 23a serving as a first semiconductor device are in contact with wirings on the wiring substrate 10 provided underneath the semiconductor device 23a. Back side solder balls 67a of the semiconductor device 23a are in contact with front side solder balls 60b of the semiconductor device 23b provided on top of the semiconductor device 23a. Namely, the semiconductor device 23a is electrically connected to any of the wirings on the wiring substrate 10 by the front side solder balls 60a. The semiconductor device 23b is electrically connected to the back side solder balls 67a of the semiconductor device 23a by the front side solder balls 60b.

The semiconductor devices 23a and 23b have the same package structure and thus the structure of only the semiconductor device 23a will be described below and description of the semiconductor device 23b is omitted.

The semiconductor device 23a according to the third embodiment includes semiconductor chips 50 and 57, gold wires 70 and 77, and the solder balls 60a and 67a on both surfaces of a substrate 40. For the sake of convenience, semiconductor chips as first semiconductor chips, a gold wire as a first gold wire, and solder balls as first solder balls provided on the front surface side of the substrate 40 are respectively called the front side semiconductor chips 50, the front side gold wire 70, and the front side solder balls 60a, and semiconductor chips as second semiconductor chips, a gold wire as a second gold wire, and solder balls as second solder balls provided on the back surface side of the substrate 40 are respectively called the back side semiconductor chips 57, the back side gold wire 77, and the back side solder balls 67a.

The semiconductor device 23a includes the substrate 40, the front side semiconductor chips 50, the front side solder balls 60a, the front side gold wire 70, a front side sealing resin 80, the back side semiconductor chips 57, the back side solder balls 67a, the back side gold wire 77, and a back side sealing resin 87. The substrate 40 has conductive wirings on its both surfaces where the semiconductor chips 50 and 57 are mounted.

The configuration on the front surface side of the substrate 40 may be the same as that of a semiconductor device according to the first embodiment. Therefore, the configuration on the back surface side of the substrate 40 will be described below and description of the configuration on the front surface side of the substrate 40 is omitted.

The plurality of back side semiconductor chips 57 are placed on a back surface of the substrate 40 and are electrically connected to any point of wirings on the substrate 40 through a back side gold wire 77. Each back side semiconductor chip 57 may be a semiconductor chip in which any integrated circuit is formed on a semiconductor substrate. For example, the semiconductor chips 57 may be NAND flash memory chips.

The back side solder balls 67a serving as back side metal balls are formed on the back surface of the substrate 40 and are electrically connected to any of the back side semiconductor chips 57 through the wirings on the substrate 40 and the back side gold wire 77. The material of the back side solder balls 67a and 67b does not necessarily need to be solder and the back side solder balls 67a and 67b may be any conductive metal ball.

The back side sealing resin 87 seals the wirings, the plurality of back side semiconductor chips 57, and the back side solder balls 67a on the back surface of the substrate 40 to protect them.

Each back side solder ball 67a is exposed from a surface 88 of the back side sealing resin 87 at a top portion 69 which is on the opposite side of a top portion 68 being in contact with the substrate 40, and protrudes from the surface 88 of the back side sealing resin 87. Namely, as viewed from the substrate 40, the top portion 69 of the back side solder ball 67a is located away from the surface 88 of the back side sealing resin 87. Note that back side solder balls 67b may have the same configuration as the back side solder balls 67a.

Next, a method of manufacturing a semiconductor device 23a will be described.

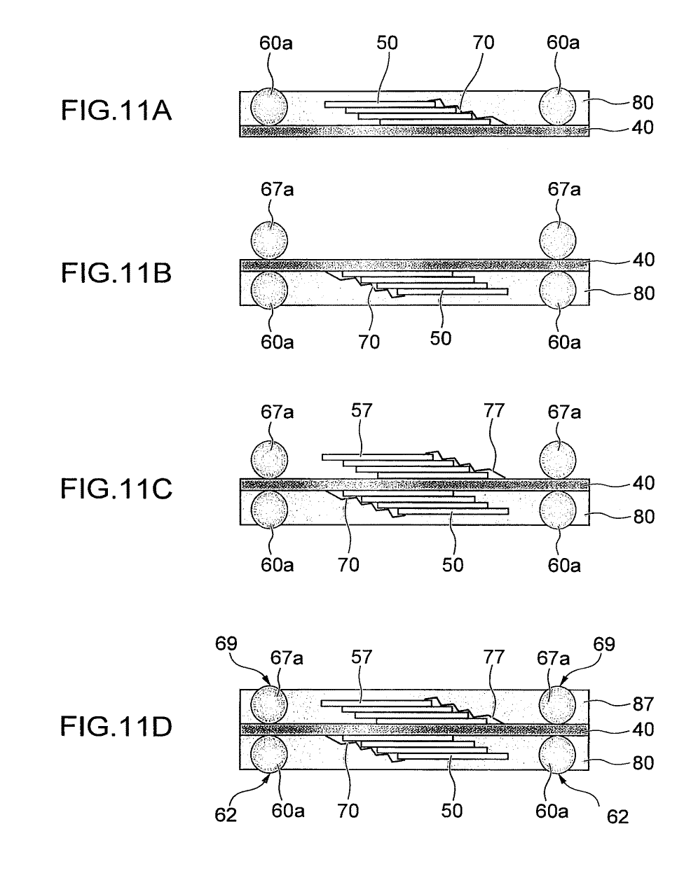

FIGS. 11A to 11D are cross-sectional views showing a method of manufacturing a semiconductor device 23a according to the third embodiment. A method of manufacturing a semiconductor device 23b is the same as the semiconductor device 23a and thus description thereof is omitted. Note that although FIGS. 11A to 11D only show cross sections of one semiconductor device 23a, in practice, a plurality of semiconductor devices 23a are formed so as to be continuously connected to each other by a substrate 40.

First, as described with reference to FIGS. 2A to 2C, front side semiconductor chips 50, a front side gold wire 70, front side solder balls 60a, and a front side sealing resin 80 are formed on a front surface of a substrate 40. By this, a cross section shown in FIG. 11A is obtained.

Then, as shown in FIG. 11B, back side solder balls 67a are provided on a back surface of the substrate 40.

Then, as shown in FIG. 11C, back side semiconductor chips 57 are placed on the back surface of the substrate 40 and are electrically connected to back surface wirings on the substrate 40 by a back side gold wire 77.

Then, as shown in FIG. 11D, the back side semiconductor chips 57, the back side gold wire 77, and the back side solder balls 67a which are mounted on the back surface of the substrate 40 are sealed with a back side sealing resin 87. At this time, while all of the plurality of back side semiconductor chips 57 and the whole back side gold wire 77 are sealed with the back side sealing resin 87, top portions 69 of the back side solder balls 67a are exposed. A method of molding the back side sealing resin 87 is the same as the method of molding a sealing resin 80 which is described with reference to FIGS. 3 and 4. By individualizing the structure shown in FIG. 11D by dicing, semiconductor devices 23a and 23b are completed which have, as shown in FIG. 10, semiconductor chips (50 and 57) and solder balls (60a and 67a) mounted on both surfaces of their respective substrates 40.

Next, a method of assembling a semiconductor package 3 will be described.

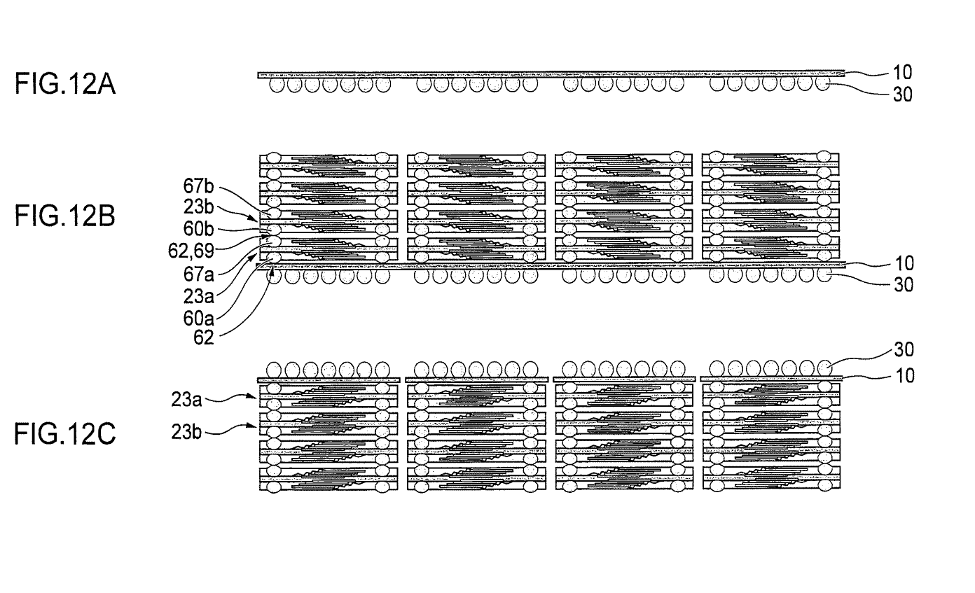

FIGS. 12A to 12C are cross-sectional views showing a method of manufacturing a semiconductor package (PoP) 3 according to the third embodiment. As shown in FIG. 12A, a wiring substrate 10 having solder balls 30 on its back surface is prepared.

Then, as shown in FIG. 12B, individualized semiconductor devices 23a and 23b are mounted on a front surface of the wiring substrate 10. A top portion 62 of each front side solder ball 60a of a semiconductor device 23a protrudes from a surface 81 of a front side sealing resin 80 and is exposed as shown in FIG. 10. Therefore, in the semiconductor device 23a, the front side solder balls 60a can be electrically connected to wirings on the wiring substrate 10 without bringing the front side sealing resin 80 into contact with the wiring substrate 10.

A top portion 62 of each front side solder ball 60b of a semiconductor device 23b also protrudes from a surface 81 of a front side sealing resin 80 and is exposed. Therefore, in the semiconductor device 23b, the front side solder balls 60b can be electrically connected to top portions 69 of back side solder balls 67a of the semiconductor device 23a without bringing the front side sealing resin 80 into contact with the semiconductor device 23a. Front side solder balls of other semiconductor devices shown in FIG. 12B can also be electrically connected to back side solder balls of other semiconductor devices present thereunderneath or to wirings on the wiring substrate 10 present thereunderneath.

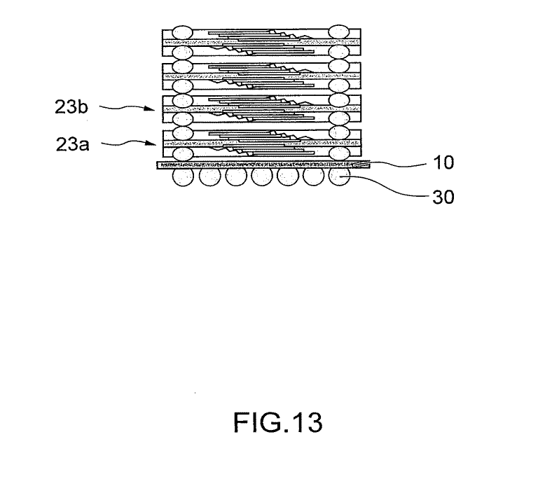

Then, as shown in FIG. 12C, semiconductor packages 3 are individualized by dicing. By this, a semiconductor package 3 having a PoP structure such as that shown in FIG. 13 is completed.

In a semiconductor device 23a (or 23b) according to the third embodiment, the same configuration as that of a semiconductor device 20a (or 20b) according to the first embodiment can be formed on both surfaces of a substrate 40. Therefore, in the semiconductor devices 23a and 23b according to the third embodiment, more semiconductor chips 50 and 57 can be mounted. Accordingly, by using the semiconductor devices 23a and 23b according to the third embodiment, the size of a semiconductor package can be further reduced. Furthermore, the third embodiment can obtain the same advantageous effects as the first embodiment.

While certain embodiments have been described, these embodiments have been presented by way of example only, and are not intended to limit the upper die of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the upper die and spirit of the inventions.

1. A semiconductor device comprising:
a substrate including wirings;
at least one first semiconductor chip mounted on a first surface of the substrate and electrically connected to any of the wirings;
a first metal ball provided on the first surface of the substrate and electrically connected to the first semiconductor chip through any of the wirings; and
a first resin that seals the wirings, the first semiconductor chip, and the first metal ball on the first surface of the substrate, wherein
a top portion of the first metal ball protrudes from a surface of the first resin and is exposed.

2. The semiconductor device according to claim 1, further comprising:
at least one second semiconductor chip mounted on a second surface of the substrate and electrically connected to any of the wirings;
a second metal ball mounted on the second surface of the substrate and electrically connected to the second semiconductor chip through any of the wirings on the substrate; and
a second resin that seals the wirings, the second semiconductor chip, and the second metal ball on the second surface of the substrate, wherein
a top portion of the second metal ball protrudes from a surface of the second resin and is exposed.

3. The semiconductor device according to claim 1, wherein the top portions of the first side metal ball and second side metal ball are further away from the substrate than top surfaces of the first semiconductor chip and second semiconductor chip, respectively.

4. The semiconductor device according to claim 2, wherein the top portions of the first side metal ball and second side metal ball are further away from the substrate than top surfaces of the first semiconductor chip and second semiconductor chip, respectively.

5. The semiconductor device according to claim 1, wherein the device is NAND-type flash EEPROM.

6. The semiconductor device according to claim 1, further comprising a second metal ball provided on a second surface of the substrate and electrically connected to the first semiconductor chip through any of the wirings.

7. A semiconductor package comprising:
a plurality of semiconductor devices, each semiconductor device including a first substrate including wirings; a plurality of semiconductor chips mounted on the first substrate and electrically connected to any of the wirings; a metal ball mounted on a first surface of the first substrate where the semiconductor chips are mounted, and electrically connected to the semiconductor chips through any of the wirings; and a resin that seals the wirings, the semiconductor chips, and the metal ball on the first surface of the first substrate, a top portion of the metal ball protruding from a surface of the resin and being exposed; and
a second substrate including wirings and the plurality of semiconductor devices placed thereon, wherein
the metal ball of each semiconductor device placed on the second substrate is in contact with any of the wirings on the second substrate or another semiconductor device placed above or underneath the semiconductor device.

8. A semiconductor package comprising:
a plurality of semiconductor devices, each semiconductor device including a first substrate including wirings; a plurality of semiconductor chips mounted on each of both surfaces of the first substrate and electrically connected to any of the wirings; a metal ball mounted on each of both surfaces of the first substrate and electrically connected to any of the semiconductor chips through any of the wirings; and a resin that seals, at each of both surfaces of the first substrate, the wirings, the semiconductor chips, and the metal ball on the first substrate, a top portion of each metal ball protruding from a surface of a corresponding resin and being exposed; and
a second substrate including wirings and the plurality of semiconductor devices placed thereon, wherein
the metal ball on a front surface of a first semiconductor device among the plurality of semiconductor devices placed on the second substrate is in contact with any of the wirings on the second substrate, and
the metal ball on a back surface of the first semiconductor device is in contact with the metal ball on a front surface of a semiconductor device present on top portion of the first semiconductor device.

9. The semiconductor package according to claim 7, wherein the device is NAND-type flash EEPROM.

10. The semiconductor package according to claim 8, wherein the device is NAND-type flash EEPROM.
